(19) United States
(12) Patent Application Publication
(10) Pub. No.: US 2026/0107829 A1
(43) Pub. Date: Apr. 16, 2026

(54) SEMICONDUCTOR MODULE

(71) Applicant: FUJI ELECTRIC CO., LTD., Kawasaki-shi (JP)

(72) Inventor: Shohei KASAI, Kawasaki-shi (JP)

(73) Assignee: FUJI ELECTRIC CO., LTD., Kawasaki-shi (JP)

(21) Appl. No.: 19/308,959

(22) Filed: Aug. 25, 2025

(30) Foreign Application Priority Data
Oct. 16, 2024 (JP) 2024-180527

(51) Int. Cl. H01L 23/04; H01L 23/00; H01L 23/10; H01L 23/498; H01L 23/538; H01L 25/07

(52) U.S. Cl. CPC H10W 76/161; H10W 70/60; H10W 70/611; H10W 76/60; H10W 90/00; H10W 90/701; H10W 90/753; H10W 90/754

(57) ABSTRACT

A semiconductor module, including: a semiconductor element; a wiring board on which the semiconductor element is mounted; a case that has a shape of a frame, to thereby form a housing space to house the semiconductor element and the wiring board; a terminal that is electrically connected to the wiring board; a lid that closes the housing space, the lid including a lid through-hole into which the terminal is inserted; an inner cover disposed in the housing space, the inner cover having an inner through-hole into which the terminal is inserted; and a sealing material disposed between the lid and the inner cover, and sealing the terminal.

### CROSS-REFERENCE TO RELATED APPLICATIONS

This application is based upon and claims the benefit of priority to Japanese Patent Application No. 2024-180527, filed on Oct. 16, 2024, the entire contents of which are incorporated herein by reference.

### BACKGROUND OF THE INVENTION

### 1. TECHNICAL FIELD

The present invention relates to a semiconductor module including a case that houses semiconductor elements and wiring boards.

### 2. DESCRIPTION OF THE RELATED ART

Typically, as a semiconductor module used for a power conversion device or the like, semiconductor modules or the like have been known that each include a case that houses semiconductor elements and wiring boards (see, for example refer to JP 2023-088099 A, JP 2022-081337 A, and WO 2024/057752 A). The semiconductor modules of these types include a semiconductor module in which terminals such as main terminals or auxiliary terminals are insert-molded with a case, and a lid that closes a housing space of semiconductor elements and wiring boards is disposed, or a semiconductor module in which a case is disposed such that terminals are inserted into through-holes of the case, and the like.

### SUMMARY OF THE INVENTION

According to, for example, a configuration where terminals are connected with boards and then a case or a lid is placed, the terminals are inserted into through-holes of the lid, and distal end portions are bent. Therefore, gaps are produced between the terminals and the through-holes of the lid. Particularly in a case where the distal end portions of the terminals are bent, a sealing material cannot be supplied to the gaps on the back side of the bent portions of the terminals. If the gaps cannot be closed as described above, a corrosive gas (such as hydrogen sulfide or sulfuric acid gas) flows in.

According to one aspect, an object of the present invention is to provide a semiconductor module that can prevent an inflow of a corrosive gas from gaps between a lid that closes a housing space of semiconductor elements, and terminals.

According to one aspect, a semiconductor module includes: a semiconductor element; a wiring board on which the semiconductor element has been mounted; a case that has a frame shape and houses the semiconductor element and the wiring board; a terminal that has been electrically connected to the wiring board; a lid that includes a lid through-hole into which the terminal is inserted, and closes the housing space of the semiconductor element and the wiring board; an inner cover that includes an inner through-hole into which the terminal is inserted, and is disposed in the housing space; and a sealing material that seals between the lid and the inner cover in surroundings of the terminal.

According to the above aspect, it is possible to prevent an inflow of a corrosive gas from gaps between the lid that closes the housing space of the semiconductor elements, and the terminals.

### BRIEF DESCRIPTION OF THE DRAWINGS

FIG. 1 is a perspective view illustrating a semiconductor module according to one embodiment;

FIG. 2 is a plan view illustrating the semiconductor module according to one embodiment;

FIG. 3 is a plan view illustrating a heat dissipation base, semiconductor elements, and wiring boards according to one embodiment;

FIG. 4 is a circuit diagram of the semiconductor module according to one embodiment;

FIG. 5 is a plan view illustrating a case with which main terminals and auxiliary terminals have been insert-molded according to one embodiment;

FIG. 6 is a plan view illustrating an inner cover, a case, and the like according to one embodiment;

FIG. 7 is a cross-sectional view taken along line VII-VII in FIG. 6;

FIG. 8 is a plan view illustrating an inner cover, a case, and the like according to a modification of one embodiment;

FIG. 9 is a plan view illustrating a case with which main terminals and auxiliary terminals have been insert-molded according to another embodiment;

FIG. 10 is a cross-sectional view taken along line X-X in FIG. 9;

FIG. 11 is a perspective view illustrating a semiconductor module according to a comparative example; and

FIG. 12 is a plan view illustrating the semiconductor module according to the comparative example.

### DETAILED DESCRIPTION

Hereinafter, a semiconductor module 1 according to one embodiment and other embodiments of the present invention will be described in detail with reference to the drawings. Note that each axis of X, Y, and Z in each figure to be referred is illustrated for the purpose of defining a direction or each plane in the illustrated semiconductor module 1 or the like. The X, Y, and Z axes are orthogonal to each other and form a right-handed system. In the following description, a Z direction may be referred to as a vertical direction. Furthermore, a surface including the X axis and the Y axis may be referred to as an upper surface or a lower surface.

Such directions and planes are terms used for convenience of description. Thus, depending on an attachment posture of the semiconductor module 1 or the like, a correspondence relationship with the X, Y, and Z directions may vary. For example, here, a surface facing a Z direction positive side (+Z direction) in a member forming the semiconductor module 1 is referred to as an upper surface, and a surface facing a Z direction negative side (−Z direction) is referred to as a lower surface. However, the surface facing the Z direction negative side may be referred to as the upper surface, and the surface facing the Z direction positive side may be referred to as the lower surface. Furthermore, here, the plan view means a case where the upper surface (XY plane) of the semiconductor module 1 or the like is viewed in a perspective manner from the Z direction positive side toward the Z direction negative side.

An aspect ratio and a magnitude relationship between respective members in each figure are merely schematically represented, and do not necessarily coincide with a relationship in the semiconductor module 1 or the like actually manufactured. For convenience of description, there is a case where the magnitude relationship between the members may be exaggerated. Furthermore, the shapes of the same members may be different between different drawings.

In the following description, as an example of the semiconductor module 1 according to the one embodiment and the other embodiments, a device is exemplified that is applied to a power conversion device such as an industrial or an in-vehicle motor inverter device. Therefore, in the following description, detailed description of the same or similar configuration, function, operation, assembly method, and the like as or to those of a known semiconductor module will be omitted.

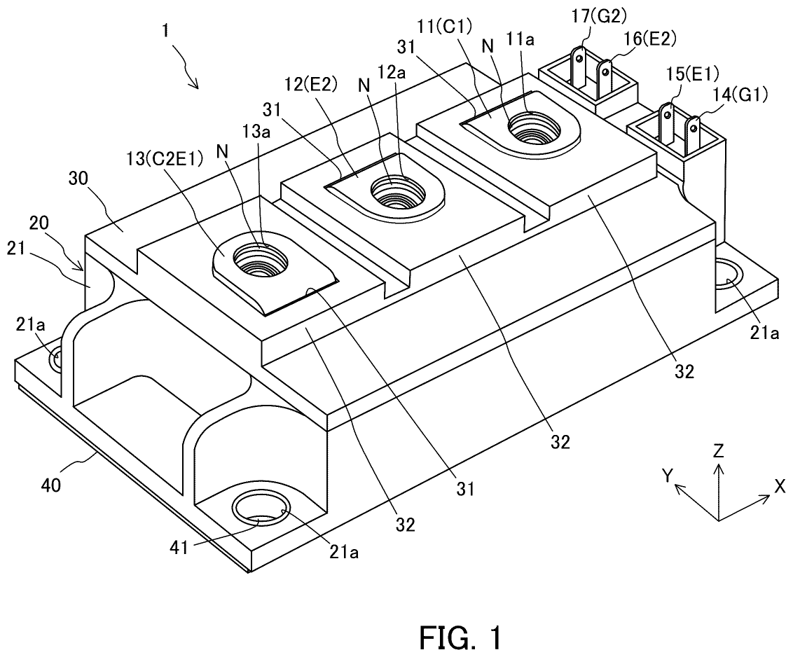

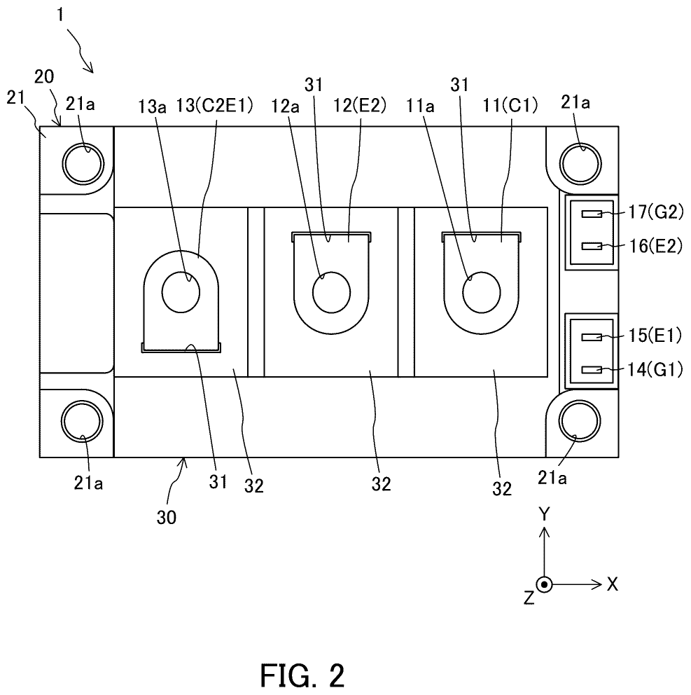

FIG. 1 is a perspective view illustrating the semiconductor module 1. FIG. 2 is a plan view illustrating the semiconductor module 1.

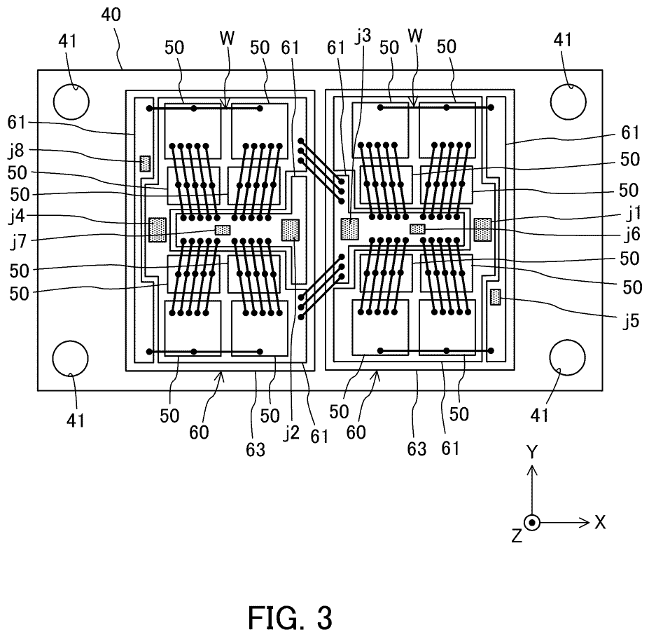

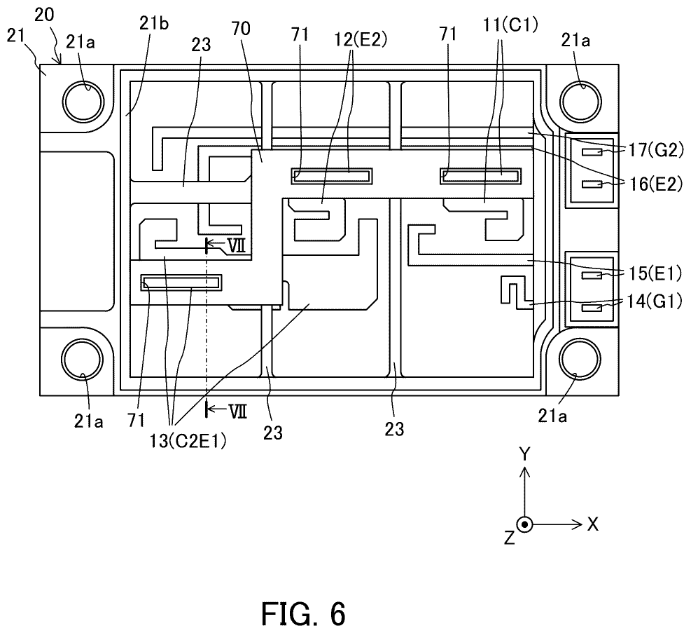

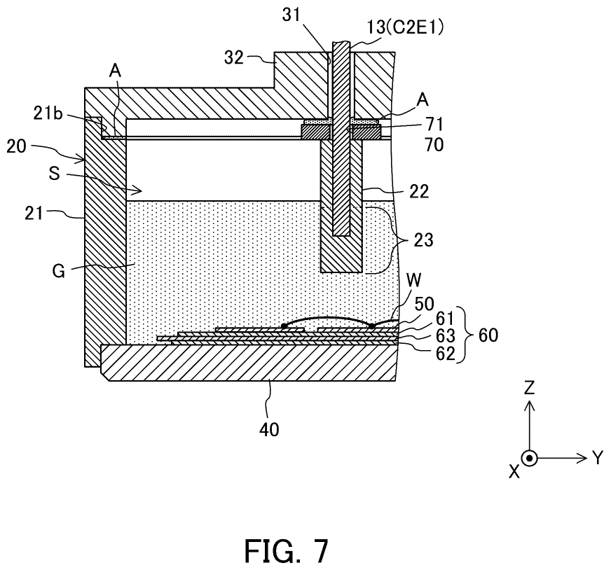

The semiconductor module 1 illustrated in FIGS. 1 and 2 includes main terminals 11 to 13, auxiliary terminals 14 to 17, a case 20, a lid 30, a heat dissipation base 40 (see FIGS. 1 and 3), a plurality of semiconductor elements 50 (see FIG. 3), a plurality of wiring boards 60 (see FIG. 3), and an inner cover 70 (see FIGS. 6 and 7).

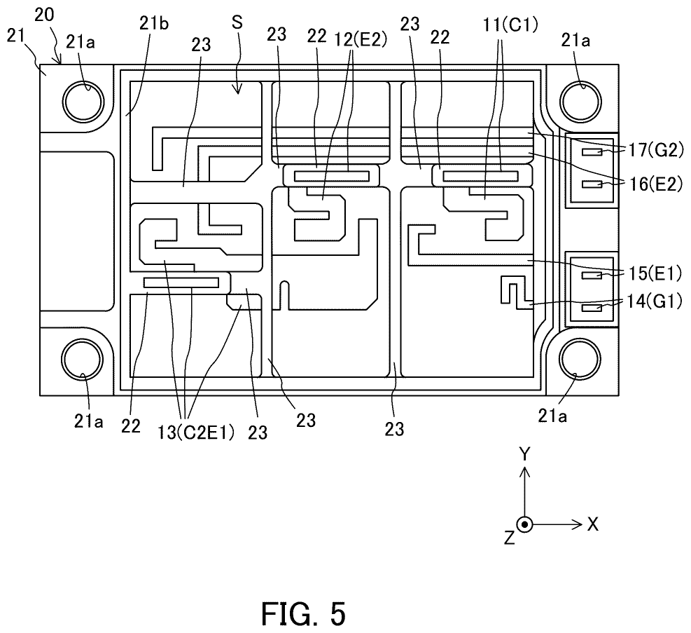

As illustrated in FIG. 5, the main terminals 11 to 13 and the auxiliary terminals 14 to 17 are insert-molded with the case 20. The main terminals 11 to 13 and the auxiliary terminals 14 to 17 are bonded to terminal bonding parts j1 to j8 such as solders of the wiring boards 60 (first conductor layers 61) illustrated in FIG. 3 to be described later, and thereby are electrically connected to the wiring boards 60.

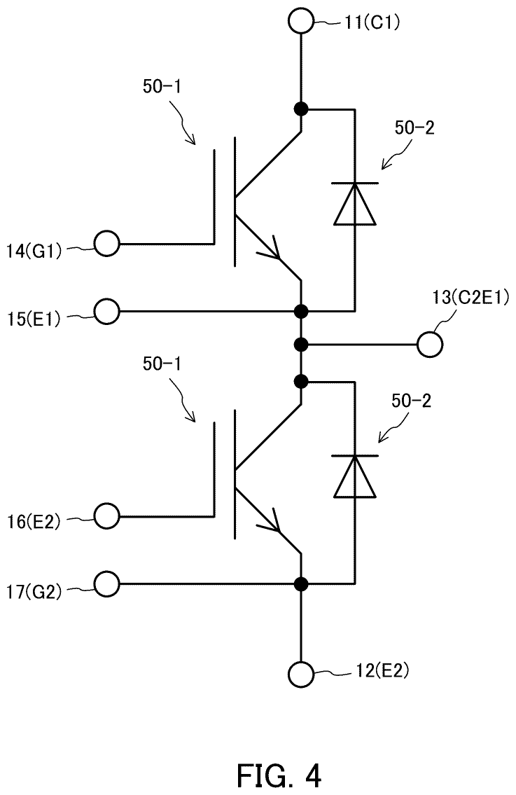

The main terminals 11 to 13 are input terminals or output terminals of the semiconductor module 1, and a main current flows therethrough. As also illustrated in FIG. 4, for example, the main terminal 11 is a C1 terminal, the main terminal 12 is an E2 terminal, and the main terminal 13 is a C2E1 terminal. As illustrated in FIGS. 3 and 5, the main terminal 11 is bonded to the terminal bonding part j1 of the first conductor layer 61, the main terminal 12 is bonded to the terminal bonding part j2 of the first conductor layer 61, and the main terminal 13 is bonded to the terminal bonding parts j3 and j4 of the first conductor layers 61.

As illustrated in FIGS. 1 and 2, each of the main terminals 11 to 13 is a plate-like metal member that is bent at a distal end portion protruding from the lid 30. For example, the distal end portions of the main terminals 11 and 12 are bent toward a Y direction negative side, and the distal end portion of the main terminal 13 is bent toward the Y direction positive side. The main terminals 11 to 13 include main terminal through-holes 11a, 12a, and 13a at the bent distal end portions. Screws of unillustrated external terminals are inserted into these main terminal through-holes 11a, 12a, and 13a.

Each of the auxiliary terminals 14 to 17 is a plate-like metal member that is bonded to each of the terminal bonding parts j5 to j8 such as solders of the wiring boards 60 (first conductor layers 61) illustrated in FIG. 3 and thereby is electrically connected to the wiring board 60 (first conductor layer 61), penetrates the case 20, and protrudes to the outside of the case 20 in a single protrusion direction (Z direction positive side). The auxiliary terminals 14 to 17 are terminals such as control terminals through which a main current does not flow. As also illustrated in FIG. 4, for example, the auxiliary terminal 14 is a G1 terminal, the auxiliary terminal 15 is an E1 terminal, the auxiliary terminal 16 is an E2 terminal, and the auxiliary terminal 17 is a G2 terminal. Note that the auxiliary terminals 14 to 17 penetrate the case 20 in a region different from a housing space S of the semiconductor elements 50 and the wiring boards 60 in the case 20.

The case 20 is formed using, for example, a thermoplastic resin material such as Poly Phenylene Sulfide (PPS) or Poly Amide (PA), and has the insulating property. As illustrated in FIG. 5, the case 20 includes a main body part 21, terminal holding parts 22, and beam parts 23, and houses the semiconductor elements 50 and the wiring boards 60 illustrated in FIGS. 3 and 7.

As illustrated in FIG. 7, for example, the case 20 is fixed to the edge of the upper surface of the heat dissipation base 40 by adhesion on the lower surface of the main body part 21. As illustrated in FIG. 1, fastening holes 21a for fixing the case 20 to an unillustrated cooler together with the heat dissipation base 40 are provided at four corners of the case 20 (main body part 21) in plan view. Furthermore, as illustrated in FIG. 5, the main body part 21 of the case 20 has a frame shape located in the surroundings of the housing space S of the semiconductor elements 50 and the wiring boards 60. The case 20 includes the main body part 21 and thereby has a frame shape as a whole.

As illustrated in FIGS. 5 and 7, the terminal holding parts 22 hold the insert-molded main terminals 11 to 13.

The beam parts 23 join the main body part 21 and the terminal holding parts 22. For example, as illustrated in FIG. 5, the beam parts 23 include the two beam parts 23 that extend in the Y direction, and the four beam parts 23 that join the two beam parts 23 and the main body part 21 and extend in the X direction in the housing space S surrounded by the main body part 21. Furthermore, the terminal holding parts 22 are provided to the three beam parts 23 of the four beam parts 23 extending in the X direction.

As illustrated in FIG. 1, the lid 30 includes three lid through-holes 31 into which the main terminals 11 to 13 are inserted, and closes an upper part (Z direction positive side) of the housing space S of the semiconductor elements 50 and the wiring boards 60 in the case 20.

The lid 30 includes three nut housing parts 32. Each of these three nut housing parts 32 is provided so as to protrude from the lid 30 toward the Z direction positive side, and a nut N is disposed therein. This nut N is located below the main terminal through-holes 11a to 13a of the main terminals 11 to 13 bent as described above. Note that the nut housing part 32 is provided with the above-described lid through-hole 31.

As illustrated in FIG. 5, it is preferable that the lid 30 is adhered with an adhesive A to a support recess part 21b provided to the main body part 21 of the case 20 so as to surround the housing space S illustrated in FIG. 7, and the edge of the lid 30 and the main body part 21 are sealed. This adhesive A can be referred to as a first lid sealing material or a lid edge sealing material. Note that the support recess part 21b may be omitted, and the upper surface of the main body part 21 and the lower surface of the edge of the lid 30 may be sealed with the adhesive A.

As an assembly order of the semiconductor module 1, for example, the terminals 11 to 17 insert-molded with the case 20 are prepared. In a prepared integral structure of the terminals 11 to 17 and the case 20, the case 20 is disposed on the wiring boards 60 so as to be bonded to the terminal bonding parts j1 to j8 illustrated in FIG. 3, and the terminals 11 to 17 and the terminal bonding parts j1 to j8 are bonded to each other. After the bonding, the inner cover 70 to be described later is disposed on the case 20 such that the main terminals 11 to 13 are inserted into inner through-holes 71 as illustrated in FIG. 6. The adhesive A is disposed on the inner cover 70. Furthermore, the lid 30 is placed on the case 20 such that the main terminals 11 to 13 are inserted into the lid through-holes 31. This lid 30 is adhered to the case 20 via the above-described support recess part 21b of the case 20, and is adhered to the inner cover 70 to be described later. Thereafter, the distal end parts of the main terminals 11 to 13 are bent as described above.

As illustrated in FIG. 3, the heat dissipation base 40 has a rectangular shape in plan view. The heat dissipation base 40 includes fastening holes 41 provided at four corners in plan view. The heat dissipation base 40 is fastened to the unillustrated cooler together with the case 20 as described above with screws to be inserted into the fastening holes 41.

The heat dissipation base 40 is a member that functions as a heat conducting member that conducts heat generated by the semiconductor elements 50 to the cooler, and is formed of, for example, a metal plate such as a copper plate or an aluminum plate.

As illustrated in FIGS. 3 and 7, the semiconductor elements 50 are mounted on the wiring boards 60. For example, the semiconductor element 50 is an Insulated Gate Bipolar Transistor (IGBT) that is a switching element 50-1 illustrated in FIG. 4, a Free Wheeling Diode (FWD) element that is a diode element 50-2, or the like. As the semiconductor element 50, another semiconductor element such as a Reverse Conducting (RC)-IGBT element in which the switching element 50-1 and the diode element 50-2 connected in antiparallel to this switching element 50-1 are integrated may be disposed. The switching element 50-1 and the diode element 50-2 in the semiconductor element 50 are not limited to be formed on a Si substrate, and may be formed on a semiconductor substrate using a wide band gap semiconductor such as Silicon Carbide (SiC) or Gallium Nitride (GaN), for example. Furthermore, the switching element 50-1 may include, for example, a SiC-Metal Oxide Semiconductor Field Effect Transistor (MOSFET), a Bipolar Junction Transistor (BJT), or the like. Furthermore, the diode element 50-2 may include, for example, a SiC-Schottky Barrier Diode (SBD), a Junction Barrier Schottky (JBS) diode, a Merged PN Schottky (MPS) diode, a PN diode, or the like.

The semiconductor element 50 is bonded to the first conductor layer 61 of the wiring board 60, and is directly or indirectly electrically connected to the other semiconductor elements 50, the first conductor layers 61 of the wiring boards 60, the main terminals 11 to 13, the auxiliary terminals 14 to 17, and the like by wirings W. The wiring W is, for example, a metallic bonding wire. The wiring W may be replaced with another wiring such as a lead formed by machining a metal plate such as a copper plate.

As illustrated in FIG. 7, the plurality of wiring boards 60 are bonded to the single common heat dissipation base 40 with a bonding material such as a solder on the lower surface (second conductor layer 62). The wiring board 60 has a rectangular shape in plan view and includes the first conductor layer 61, the second conductor layer 62, and an insulating layer 63. The wiring board 60 may be, for example, a Direct Copper Bonding (DCB) substrate or an Active Metal Brazing (AMB) substrate. The wiring board 60 may be referred to as a laminated substrate, an insulating circuit substrate, an insulating heat dissipation circuit substrate, or the like.

The first conductor layer 61 is, for example, a member that functions as a wiring member in an inverter circuit and is provided to be separated as a plurality of parts as a metal plate, a metal foil, or the like of copper, aluminum, or the like on the upper surface of the insulating layer 63. The first conductor layer 61 is electrically connected to the other first conductor layers 61, the semiconductor elements 50, the main terminals 11 to 13, the auxiliary terminals 14 to 17, and the like by the wirings W. The first conductor layer 61 may be referred to as a conductor plate, a conductor pattern, a conductive layer, a wiring pattern, or the like.

The second conductor layer 62 is, for example, a member that functions as a heat conducting member that conducts heat generated in the inverter circuit to the heat dissipation base 40 and is provided as a metal plate, a metal foil, or the like of copper, aluminum, or the like on the lower surface of the insulating layer 63. The second conductor layer 62 (wiring board 60) is bonded to the heat dissipation base 40 with the bonding material such as a solder. The second conductor layer 62 may be referred to as a heat dissipation layer, a heat dissipation plate, a heat dissipation pattern, a conductor pattern, or the like.

The insulating layer 63 is, for example, a ceramic substrate. Although the insulating layer 63 is not limited to a specific substrate, the insulating layer 63 may be, for example, a ceramic substrate formed of a ceramic material such as aluminum nitride (AlN), aluminum oxide (Al₂O₃), silicon nitride (Si₃N₄), or a composite material of aluminum oxide (Al₂O₃) and zirconium oxide (ZrO₂). The insulating layer 63 may be, for example, a substrate obtained by molding an insulating resin such as an epoxy resin, a substrate obtained by impregnating a base material such as a glass fiber with an insulating resin, a substrate obtained by coating a surface of a flat plate-like metal core with an insulating resin, or the like.

Note that the shapes, the number of arrangement, arrangement locations, and the like of the main terminals 11 to 13, the auxiliary terminals 14 to 17, the semiconductor elements 50, and the wiring boards 60 can be appropriately changed. It is desirable that the pluralities of the main terminals 11 to 13, the auxiliary terminals 14 to 17, the semiconductor elements 50, and the wiring boards 60 are disposed. However, the numbers of the semiconductor elements 50 and the wiring boards 60 in particular can be any number. Furthermore, as illustrated in FIG. 7, the semiconductor elements 50 and the wiring boards 60 are preferably sealed with a sealing material such as a sealing gel G or an epoxy resin. Note that the sealing gel G is located above the upper ends of the beam parts 23, yet may be located below the upper ends of the terminal holding parts 22.

The inner cover 70 illustrated in FIGS. 6 and 7 includes the three inner through-holes 71 into which the main terminals 11 to 13 are inserted, and is disposed in the housing space S. The inner cover 70 is preferably formed in a flat plate shape using a resin material, for example. The thickness of the inner cover 70 depends on the sealing gel G and the distance in the Z direction between the terminal holding parts 22 and the lid 30, yet is, for example, 1.5 mm to 1.8 mm. The inner cover 70 is preferably supported by the three terminal holding parts 22. The inner cover 70 may be merely placed on the terminal holding parts 22, yet may be fixed to the terminal holding parts 22 by adhesion or the like.

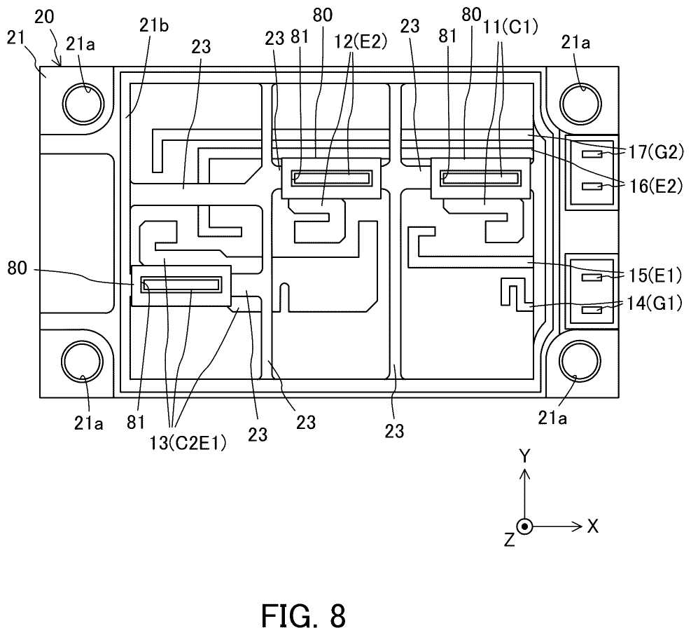

Note that, if the inner cover 70 includes the three (an example of a plural number) inner through-holes 71, the single inner cover 70 can be provided instead of providing the inner covers 70 the number of which is the same as the number of the main terminals 11 to 13. However, as illustrated in FIG. 8 (a modification of the present embodiment), three inner covers 80 the number of which is the same as the number of the main terminals 11 to 13 may be disposed. In this case, each of the three inner covers 80 includes an inner through-hole 81 and is supported by the terminal holding part 22.

As illustrated in FIG. 7, after the inner cover 70 is placed on the terminal holding parts 22 (case 20), the adhesive A that is an example of the sealing material is disposed on the upper surface of the inner cover 70. This adhesive A is, for example, a silicone-based adhesive, and is disposed in an arbitrary shape such as a sheet shape. Note that this adhesive A can also be referred to as a second lid sealing material.

Furthermore, when the lid 30 is placed on the case 20, the adhesive A is pushed and spread in the surroundings of the main terminals 11 to 13 to seal between the lid 30 and the inner cover 70. To seal between the lid 30 and the inner cover 70 as described above, the adhesive A is preferably supplied so as to surround the main terminals 11 to 13 over the entire circumference (360 degrees in plan view) of the surroundings of the main terminals 11 to 13, and is provided so as to be adhered to the main terminals 11 to 13 over the entire circumference of the surroundings.

Here, to insert the main terminals 11 to 13, the lid 30 is provided with the lid through-holes 31, and the inner cover 70 is provided with the inner through-holes 71. Accordingly, the adhesive A is preferably disposed in close contact with the main terminals 11 to 13 over the entire circumference of the surroundings of the main terminals 11 to 13 such that the lid through-holes 31 and the inner through-holes 71 do not communicate with each other. Here, part of the adhesive A pushed and spread by the lid 30 may enter the inner through-holes 71 of the inner cover 70 or the lid through-holes 31 of the lid 30. Note that it is possible to fix the lid 30 and the inner cover 70 by using the adhesive A as the sealing material for sealing between the lid 30 and the inner cover 70 in the surroundings of the main terminals 11 to 13. In this regard, a sealing material having no adhesiveness may be disposed instead of the adhesive A.

Note that, in the present embodiment, since only the main terminals 11 to 13 among the main terminals 11 to 13 and the auxiliary terminals 14 to 17 are inserted into the lid through-holes 31 of the lid 30, the adhesive A seals between the lid 30 and the inner cover 70 in the surroundings of the main terminals 11 to 13. In this regard, in the configuration where the auxiliary terminals 14 to 17 are inserted into the lid through-holes 31 of the lid 30, it is preferable to seal between the lid 30 and the inner cover 70 in the surroundings of the auxiliary terminals 14 to 17 with a sealing material such as the adhesive A.

Furthermore, in the present embodiment, the main terminals 11 to 13 (and the auxiliary terminals 14 to 17) are insert-molded with the case 20. However, the main terminals 11 to 13 may not be insert-molded with the case 20. In this case, since gaps between the main terminals 11 to 13 and the case 20 may become large, it is particularly effective that the adhesive A is disposed in close contact with the main terminals 11 to 13 over the entire circumference of the surroundings of the main terminals 11 to 13.

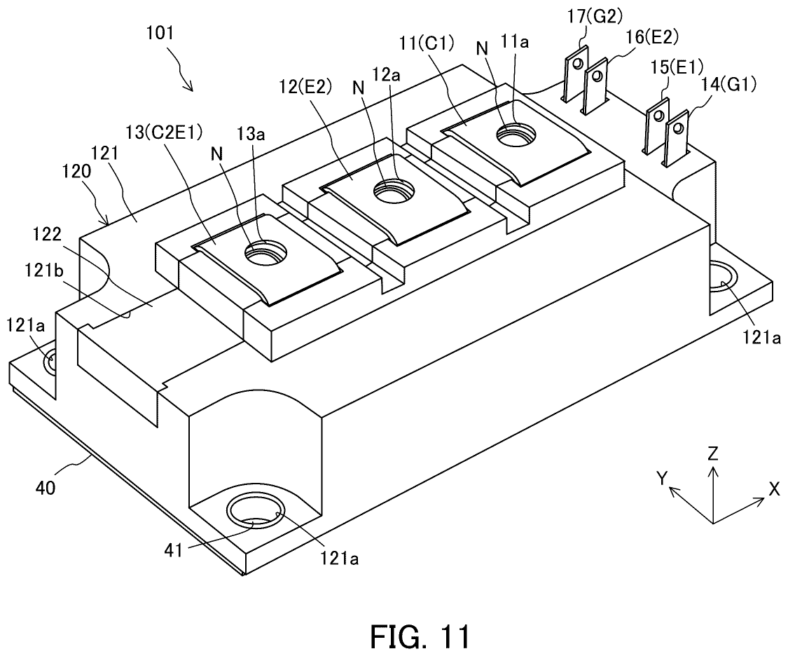

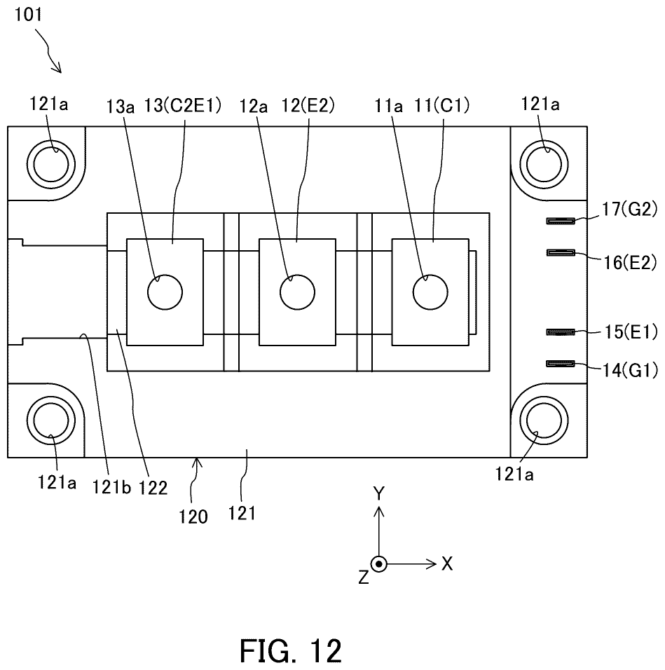

FIGS. 11 and 12 are a perspective view and a plan view illustrating a semiconductor module 101 according to a comparative example.

The semiconductor module 101 illustrated in FIGS. 11 and 12 mainly differs from the semiconductor module 1 according to the present embodiment in that a case 120 is not insert-molded with the main terminals 11 to 13 and the auxiliary terminals 14 to 17, and the lid 30 is omitted.

The case 120 includes a main body part 121 and a nut globe 122 that is disposed in an opening part 121b of this main body part 121 and fixes screws of the above-described external terminals to the main terminals 11 to 13. Note that, in the present comparative example, the main terminals 11 to 13 are metal members whose distal end portions are not bent as described above, and that have downward U-shaped plate shapes.

Fastening holes 121a for fixing the case 120 to the unillustrated cooler together with the heat dissipation base 40 are provided at four corners of the main body part 121. After the main body part 121 is placed above the semiconductor elements 50 and the wiring boards 60 such that the main terminals 11 to 13 and the auxiliary terminals 14 to 17 are exposed to the outside, the nut globe 122 is inserted from the end portion on the X direction negative side to the X direction positive side of the opening part 121b of the main body part 121. Thus, in a state where the nut globe 122 sandwiches the main terminals 11 to 13 between the nut globe 122 and a sidewall of the opening part 121b, the nuts N of the nut globe 122 are located below the main terminal through-holes 11a, 12a, and 13a of the main terminals 11 to 13.

In the present comparative example, in the case 120, a gap is produced between the opening part 121b of the main body part 121 and the nut globe 122. This gap can be sealed with a sealing material such as an adhesive from the outside of the case 120, yet the sealing material cannot be supplied to the gaps on the back side of the main terminals 11 to 13. Furthermore, when the sealing material is supplied from the outside of the case 120, the appearance deteriorates, and the sealing material is readily peeled off. When the sealing material is peeled off, not only peeled-off waste is produced, but also a corrosive gas flows in from the gaps.

The fact that it is difficult to close from the outside the gaps with the sealing material as described above is the same in the aspect where the inner cover 70 and the adhesive A for sealing between this inner cover 70 and the lid 30 are omitted, and the adhesive A is supplied between the lid through-holes 31 and the main terminals 11 to 13 from the outside of the lid 30 in the present embodiment.

According to the above-described present embodiment, the semiconductor module 1 includes: the semiconductor elements 50: the wiring boards 60 on which these semiconductor elements 50 have been mounted; the case 20 that has the frame shape and houses the semiconductor elements 50 and the wiring boards 60; the mains terminals 11 to 13 that are examples of the terminals electrically connected to the wiring boards 60; the lid 30 that includes the lid through-holes 31 into which these main terminals 11 to 13 are inserted, and closes the housing space S of the semiconductor elements 50 and the wiring boards 60; the inner cover 70 that includes the inner through-holes 71 into which the main terminals 11 to 13 are inserted, and is disposed in the housing space S; and the adhesive A that is an example of a sealing material for sealing between the lid 30 and the inner cover 70 in the surroundings of the main terminals 11 to 13.

By sealing between the lid 30 and the inner cover 70 in the surroundings of the main terminals 11 to 13 as described above, it is possible to prevent an inflow of a corrosive gas (such as hydrogen sulfide or sulfuric acid gas) from the lid through-holes 31 of the lid 30. Accordingly, according to the present embodiment, it is possible to prevent the inflow of the corrosive gas from the gaps between the lid 30 that closes the housing space S of the semiconductor elements 50, and the main terminals 11 to 13 (terminals). Consequently, it is possible to suppress growth of corrosion products such as dendrite (dendritic crystal) and suppress dielectric breakdown as a result inside the semiconductor module 1, and improve reliability of the semiconductor module 1. Furthermore, the semiconductor module 1 can be used in a highly corrosive environment, so that application of the semiconductor module 1 expands. Furthermore, in the present embodiment, the adhesive A does not fill the gaps between the lid through-holes 31 and the main terminals 11 to 13 outside the lid 30, but seals between the lid 30 and the inner cover 70 inside the lid 30, so that it is possible to suppress deterioration of appearance due to exposure of the adhesive A. Furthermore, the adhesive A is hardly peeled off compared to an aspect where the adhesive A is supplied to the outside of the lid 30, so that it is possible to reliably prevent an inflow of a corrosive gas.

Furthermore, in the present embodiment, the sealing material (adhesive A) for sealing between the lid 30 and the inner cover 70 is disposed in close contact with the main terminals 11 to 13 over the entire circumference of the surroundings of the main terminals 11 to 13.

Consequently, it is also possible to prevent the inflow of the corrosive gas from the inner through-holes 71 due to communication between the lid through-holes 31 (outside) of the lid 30 and the inner through-holes 71 of the inner cover 70. Accordingly, it is possible to further prevent the inflow of the corrosive gas from the gaps between the lid 30 and the main terminals 11 to 13 (terminals).

Furthermore, in the present embodiment, the main terminals 11 to 13 are insert-molded with the case 20.

Consequently, it is also possible to prevent the inflow of the corrosive gas from the gap between the main terminal 11 and the terminal holding part 22 (case 20). Accordingly, it is possible to further prevent the inflow of the corrosive gas from the gaps between the lid 30 and the main terminals 11 to 13 (terminals).

Furthermore, in the present embodiment, the case 20 includes the main body part 21 that has the frame shape and is located in the surroundings of the housing space S of the semiconductor elements 50 and the wiring boards 60, the terminal holding parts 22 that hold the main terminals 11 to 13, and the beam parts 23 that join the main body part 21 and the terminal holding parts 22.

Consequently, the terminal holding parts 22 can hold the main terminals 11 to 13 in the housing space S of the semiconductor elements 50 and the wiring boards 60. Consequently, it is also possible to suppress the inflow of the corrosive gas from the inner through-holes 71 of the inner cover 70. Accordingly, it is possible to further prevent the inflow of the corrosive gas from the gaps between the lid 30 and the main terminals 11 to 13 (terminals).

Furthermore, in the present embodiment, the inner cover 70 is supported by the terminal holding parts 22.

Consequently, it is possible to stabilize the position of the inner cover 70, and more reliably seal between the lid 30 and the inner cover 70. Accordingly, it is possible to further prevent the inflow of the corrosive gas from the gaps between the lid 30 and the main terminals 11 to 13 (terminals).

Furthermore, in the present embodiment, the inner cover 70 includes the plurality of inner through-holes 71 into which the main terminals 11 to 13 are inserted.

Consequently, compared to the aspect where an inner cover 80 is disposed for each of the main terminals 11 to 13 as in the modification illustrated in FIG. 8, it is possible to prevent the inflow of the corrosive gas from the gaps between the lid 30 and the main terminals 11 to 13 (terminals) with a simple configuration.

Furthermore, in the present embodiment, the sealing material for sealing between the lid 30 and the inner cover 70 in the surroundings of the main terminals 11 to 13 is the adhesive A.

Consequently, it is possible to fix the lid 30 and the inner cover 70 with the adhesive A used for sealing, and stabilize the position of the inner cover 70, so that it is possible to more reliably seal between the lid 30 and the inner cover 70. Accordingly, it is possible to further prevent the inflow of the corrosive gas from the gaps between the lid 30 and the main terminals 11 to 13 (terminals). Furthermore, the adhesive A surrounds the surroundings of the main terminals 11 to 13 by 360 degrees to adhere in this aspect, so that it is possible to completely block an inflow path of the corrosive gas and prevent an adverse effect of the corrosive gas.

Furthermore, in the present embodiment, the terminals around which the lid 30 and the inner cover 70 are sealed are the main terminals 11 to 13.

Therefore, the main terminals 11 to 13 are larger than the auxiliary terminals 14 to 17, so that it is possible to prevent the inflow of a corrosive gas from the gaps between the lid 30 and the main terminals 11 to 13 for which the gaps are readily produced between the main terminals 11 to 13 and the lid 30, and that are readily disposed so as to extend upward (Z direction positive side) in the housing space S.

Furthermore, in the present embodiment, the main terminals 11 to 13 are bent at the distal end portions protruding from the lid 30.

Consequently, the inflow of the corrosive gas from the back side of the bent portions that are difficult to close in the gaps between the main terminals 11 to 13 and the lid through-holes 31 of the lid 30 can be prevented with the adhesive A for sealing the gap between the lid 30 and the inner cover 70.

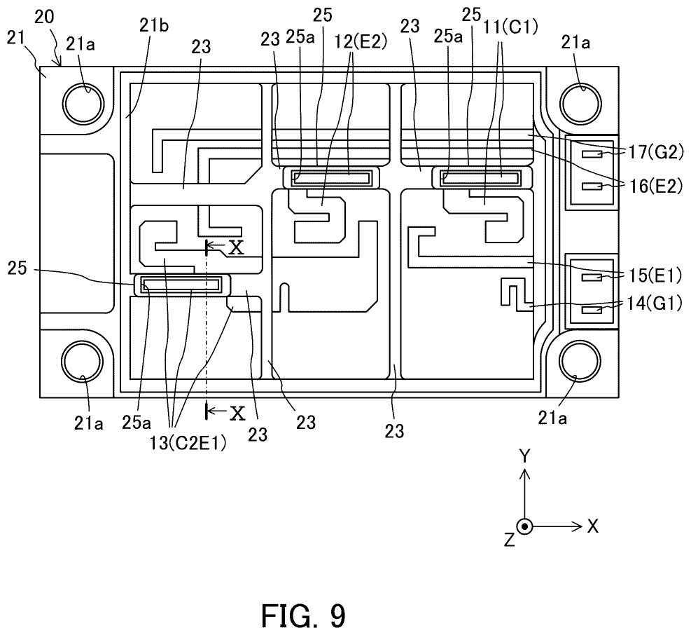

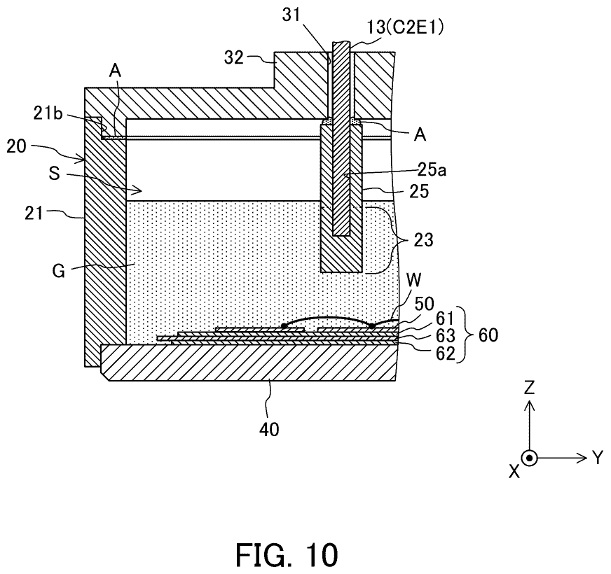

FIG. 9 is a plan view illustrating the case 20 in which the main terminals 11 to 13 and the auxiliary terminals 14 to 17 are insert-molded according to another embodiment. FIG. 10 is a cross-sectional view taken along line X-X in FIG. 9.

In the present embodiment, instead of the inner covers 70 and 80 supported by the terminal holding parts 22, three inner covers 25 are integrally provided to the case 20. Since other matters can be configured similarly to those in the above-described description, detailed description is omitted.

In the present embodiment, not the terminal holding parts 22 but the inner covers 25 are joined with the main body part 21 by the beam parts 23. Furthermore, the three inner covers 25 hold the main terminals 11 to 13. Hence, as illustrated in FIG. 10, the inner covers 25 extend longer toward the Z direction positive side than the terminal holding parts 22 illustrated in FIG. 7.

As illustrated in FIG. 10, the adhesive A that is the example of the sealing material is disposed on the upper surfaces of the inner covers 25. Furthermore, when the lid 30 is placed on the case 20, the adhesive A is pushed and spread in the surroundings of the main terminals 11 to 13 to seal between the lid 30 and the inner covers 25. Here, the main terminals 11 to 13 are insert-molded with the inner covers 25, so that a gap is not substantially produced between inner through-holes 25a of the inner covers 25 and the main terminals 11 to 13. In this regard, the adhesive A is preferably disposed in close contact with the main terminals 11 to 13 over the entire circumference of the surroundings of the main terminals 11 to 13. Part of the adhesive A pushed and spread by the lid 30 may enter the lid through-holes 31 of the lid 30. By using the adhesive A as a sealing material for sealing between the lid 30 and the inner covers 25 in the surroundings of the main terminals 11 to 13, it is possible to fix the lid 30 and the inner covers 25 (case 20). In this regard, a sealing material having no adhesiveness may be disposed instead of the adhesive A. Note that only the one inner cover 25 may be provided instead of the three (an example of a plural number) inner covers 25, and the integrally provided single inner cover 25 may hold the three main terminals 11 to 13.

According to the above-described other embodiments, it is possible to obtain the same effects as for the same matters as those of the above-described one embodiment, that is, the effect that it is possible to prevent the inflow of the corrosive gas from the gaps between the lid 30 that closes the housing space S of the semiconductor elements 50, and the main terminals 11 to 13 (terminals).

Furthermore, in the above-described other embodiment, the inner covers 25 are provided integrally with the case 20 and hold the main terminals 11 to 13. The case 20 includes the main body part 21 that has the frame shape and is located in the surroundings of the housing space S, and the beam parts 23 that join this main body part 21 and the inner covers 25.

Consequently, it is possible to prevent the inflow of the corrosive gas from the gaps between the lid 30 and the main terminals 11 to 13 (terminals) with a simple configuration compared to an aspect where the inner covers 70 and 80 are disposed separately from the case 20.

The semiconductor module according to the present invention is not limited to the embodiment described above, and various changes, substitutions, and modifications may be made without departing from the spirit of the technical concept. Furthermore, if the technical idea can be achieved in another manner due to the progress of the technology or by another derived technology, the technical idea may be carried out by using the manner. Therefore, the claims cover all embodiments that may be included within the scope of the technical idea.

Hereinafter, some inventions described in the specification and drawings of the present application will be additionally described.

### <Supplementary Note 1>

A semiconductor module including:
a semiconductor element;
a wiring board on which the semiconductor element has been mounted;
a case that has a frame shape and houses the semiconductor element and the wiring board;
a terminal that has been electrically connected to the wiring board;
a lid that includes a lid through-hole into which the terminal is inserted, and closes the housing space of the semiconductor element and the wiring board;
an inner cover that includes an inner through-hole into which the terminal is inserted, and is disposed in the housing space; and
a sealing material that seals between the lid and the inner cover in surroundings of the terminal.

### <Supplementary Note 2>

The semiconductor module described in supplementary note 1, in which
the sealing material is disposed in close contact with the terminal over an entire circumference of the surroundings of the terminal.

### <Supplementary Note 3>

The semiconductor module described in supplementary note 1 or 2, in which
the terminal is insert-molded with the case.

### <Supplementary Note 4>

The semiconductor module described in supplementary note 3, in which
the case includes a main body part that has a frame shape and is located in the surroundings of the housing space, a terminal holding part that holds the terminal, and a beam part that joins the main body part and the terminal holding part.

### <Supplementary Note 5>

The semiconductor module described in supplementary note 4, in which
the inner cover is supported by the terminal holding part.

### <Supplementary Note 6>

The semiconductor module described in supplementary note 5, in which
the inner cover includes a plurality of the inner through-holes.

### <Supplementary Note 7>

The semiconductor module described in supplementary note 3, in which
the inner cover is provided integrally with the case and holds the terminal, and
the case includes a main body part that has a frame shape and is located in the surroundings of the housing space, and a beam part that joins the main body part and the inner cover.

### <Supplementary Note 8>

The semiconductor module described in any one of supplementary notes 1 to 7, in which
the sealing material is an adhesive.

### <Supplementary Note 9>

The semiconductor module described in any one of supplementary notes 1 to 8, in which
the terminal is a main terminal.

### <Supplementary Note 10>

The semiconductor module described in any one of supplementary notes 1 to 9, in which
the terminal is bent at a distal end portion protruding from the lid.

As described above, the present invention has an effect that it is possible to prevent an inflow of a corrosive gas from gaps between a lid that closes a housing space of semiconductor elements, and terminals, and is particularly useful for industrial or electrical inverter devices.

What is claimed is:

1. A semiconductor module, comprising:
a semiconductor element;
a wiring board on which the semiconductor element is mounted;
a case that has a shape of a frame, to thereby form a housing space to house the semiconductor element and the wiring board;
a terminal that is electrically connected to the wiring board;
a lid that closes the housing space, the lid including a lid through-hole into which the terminal is inserted;
an inner cover disposed in the housing space, the inner cover having an inner through-hole into which the terminal is inserted; and
a sealing material disposed between the lid and the inner cover, and sealing the terminal.

2. The semiconductor module according to claim 1, wherein
the sealing material is disposed in close contact with the terminal over an entire circumference of the terminal.

3. The semiconductor module according to claim 1, wherein
the terminal is insert-molded with the case.

4. The semiconductor module according to claim 3, wherein the case includes:
a main body part that is of the shape of the frame to surround the housing space,
a terminal holding part that holds the terminal, and
a beam part that joins the main body part and the terminal holding part.

5. The semiconductor module according to claim 4, wherein
the inner cover is supported by the terminal holding part.

6. The semiconductor module according to claim 5, wherein
the inner through-hole is provided in a plurality in the inner cover.

7. The semiconductor module according to claim 3, wherein
the inner cover is provided integrally with the case and holds the terminal, and
the case includes:
a main body part that is of the shape of the frame to surround the housing space, and
a beam part that joins the main body part and the inner cover.

8. The semiconductor module according to claim 1, wherein
the sealing material is an adhesive.

9. The semiconductor module according to claim 1, wherein
the terminal is a main terminal.

10. The semiconductor module according to claim 1, wherein
the terminal is bent at a distal end portion protruding from the lid.
